(19) United States
(12) Patent Application Publication
(10) Pub. No.: US 2014/0368555 A1
(43) Pub. Date: Dec. 18, 2014

(54) DISPLAY APPARATUS AND METHOD OF DRIVING THE SAME

(71) Applicant: Samsung Display Co., Ltd., Yongin-city (KR)

(72) Inventor: Jun NAMKUNG, Asan-si (KR)

(73) Assignee: Samsung Display Co., Ltd., Yongin-city (KR)

(21) Appl. No.: 14/278,071

(22) Filed: May 15, 2014

(30) Foreign Application Priority Data
Jun. 18, 2013 (KR) 10-2013-0069528

(51) Int. Cl. H01L 51/52; G09G 3/32; H01L 27/32

(52) U.S. Cl. CPC H01L 51/5218; H01L 27/3241; H01L 51/5221; G09G 3/3208
USPC 345/690; 257/40; 345/76

(57) ABSTRACT

Provided is a display apparatus including: a first substrate; a first electrode disposed on the first substrate; an organic emission layer disposed on the first electrode and configured to generate light; a ferromagnetic electrode disposed on the organic emission layer and configured to control a spin of the light; a second electrode disposed on the ferromagnetic electrode, the second electrode opposing the first electrode; a polarizer disposed on the second electrode and configured to selectively transmit and convert at least part of the light, the polarizer comprising at least two laminated layers; and a second substrate disposed on the polarizer, the second substrate opposing the first substrate.

### CROSS REFERENCE TO RELATED APPLICATION

This application claims priority, under 35 U.S.C. §119, from and the benefit of Korean Patent Application No. 10-2013-0069528, filed on Jun. 18, 2013, which is hereby incorporated by reference for all purposes as if fully set forth herein.

### BACKGROUND

1. Field

Exemplary embodiments of the present disclosure relate to a display apparatus. More particularly, exemplary embodiments of the present disclosure relate to a display apparatus and a method of driving the same.

2. Discussion of the Background

When a display apparatus is operated in the external environment, the image quality of the display apparatus is dramatically reduced by the reflection of external light. In order to prevent the external light reflection, the display apparatus may include a polarizer.

However, when the light emitted from the organic emission layer of a display apparatus passes through the polarizer, the brightness of the light is reduced by more than half.

As a result, the brightness of the light emitted from the organic emission layer suffers a significant loss, while passing through the polarizer of the display apparatus.

### SUMMARY

Various exemplary embodiments of the present disclosure provide a display apparatus for improving the brightness of the display light.

Various exemplary embodiments of the present disclosure provide a method of driving the above-mentioned display apparatus.

According to one exemplary embodiment, a display apparatus includes a first substrate; a first electrode disposed on the first substrate; an organic emission layer disposed on the first electrode and configured to generate light; a ferromagnetic electrode disposed on the organic emission layer and configured to control a spin of the light; a second electrode disposed on the ferromagnetic electrode, the second electrode opposing the first electrode; a polarizer disposed on the second electrode and configured to selectively transmit and convert at least part of the light, the polarizer comprising at least two laminated layers; and a second substrate disposed on the polarizer, the second substrate opposing the first substrate.

In accordance with one exemplary embodiment, a method of driving a display apparatus includes: generating light; passing the light through a ferromagnetic electrode to convert a polarization state of the light; passing the light through a second electrode; passing the light through a λ/4 phase retardation layer, thereby converting the light into right-circularly polarized light; converting the light to vibrate up and down; passing the light through a linear polarization layer; and passing the light vibrating up and down through a second substrate to enable a display of an image.

In accordance with one exemplary embodiment, a method of driving a display apparatus includes: generating light; passing the light through a ferromagnetic electrode to convert the light into right-circularly polarized light; causing the light to separate into first light and second light, the first light passing through a second electrode, and the second light being reflected from the second electrode; converting the second light into left-circularly polarized light; passing the second light through a retardation layer; converting the passed second light into right-circularly polarized light; reflecting the second light from a first electrode; converting the reflected second light into left-circularly polarized light; passing the second light through the retardation layer; converting the second light into right-circularly polarized light; passing the second light through the second electrode; superposing the first light and the second light in the form of the right-circular polarized light to generate third light; passing the third light through a λ/4 phase retardation layer, the superposed third light being the right-circular polarized light; converting the third light to vibrate up and down; passing the third light through a linear polarization layer; and passing the light through a second substrate to enable a display of an image.

In one exemplary embodiment, a display apparatus includes: a first substrate; a first electrode disposed on the first substrate; an organic emission layer disposed on the first electrode and configured to generate light; a ferromagnetic electrode disposed on the organic emission layer configured to control a spin of the light, the ferromagnetic electrode opposing the first electrode; a polarizer disposed on the ferromagnetic electrode and configured to selectively transmit and convert at least part of the light, the polarizer comprising at least two laminated layers; and a second substrate disposed on the polarizer, the second substrate opposing the first substrate.

In accordance with various exemplary embodiments, a display apparatus has a ferromagnetic electrode, so that the brightness of the light emitted outward may not be reduced as much after passing through the polarizer. It is to be understood that both the foregoing general description and the following detailed description are exemplary and explanatory and are intended to provide further explanation of the invention as claimed.

### BRIEF DESCRIPTION OF THE DRAWINGS

Various exemplary embodiments of the present disclosure can be understood in more detail from the following description taken in conjunction with the accompanying drawings.

FIG. 1 is a cross-sectional view illustrating a display element in accordance with one exemplary embodiment of the present invention.

FIG. 2 is a cross-sectional view illustrating a display apparatus in accordance with one exemplary embodiment of the present invention.

FIG. 3 is a cross-sectional view illustrating a display apparatus in accordance with one exemplary embodiment of the present invention.

FIGS. 4A to 4F are cross-sectional views illustrating a method of driving the display apparatus of FIG. 2.

FIG. 5 is a cross-sectional view illustrating a display element in accordance with one exemplary embodiment of the present invention.

FIG. 6 is a cross-sectional view illustrating a display apparatus in accordance with one exemplary embodiment of the present invention.

FIG. 7 is a cross-sectional view illustrating the display apparatus in accordance with one exemplary embodiment of FIG. 6.

FIGS. 8A to 8J are cross-sectional views illustrating a method of driving the display apparatus of FIG. 6.

FIG. 9 is a cross-sectional view illustrating a display element in accordance with one exemplary embodiment of the present invention.

FIG. 10 is a cross-sectional view illustrating a display apparatus in accordance with one exemplary embodiment of the present invention.

FIG. 11 is a cross-sectional view illustrating the display apparatus in accordance with one exemplary embodiment of FIG. 10.

FIG. 12 is a cross-sectional view illustrating a display element in accordance with one exemplary embodiment of the present invention.

FIG. 13 is a cross-sectional view illustrating a display apparatus in accordance with one exemplary embodiment of the present invention.

FIG. 14 is a cross-sectional view illustrating the display apparatus in accordance to with one exemplary embodiment of FIG. 13.

FIG. 15 is a cross-sectional view illustrating a display element in accordance with one exemplary embodiment of the present invention.

FIG. 16 is a cross-sectional view illustrating a display apparatus in accordance with one exemplary embodiment of the present invention.

### DETAILED DESCRIPTION OF THE ILLUSTRATED EMBODIMENTS

The exemplary embodiments are described more fully hereinafter with reference to the accompanying drawings. The inventive concept may, however, be embodied in many different forms and should not be construed as limited to the exemplary embodiments set forth herein. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like or similar reference numerals generally refer to like or similar elements throughout. As used herein, the term “and/or” includes any and all combinations of one or more of the associated listed items.

It will be understood that, although the terms first, second, third etc. may be used herein to describe various elements, components, regions, layers, patterns and/or sections, these elements, components, regions, layers, patterns and/or sections should not be limited by these terms. These terms are only used to distinguish one element, component, region, layer pattern or section from another region, layer, pattern or section. Thus, a first element, component, region, layer or section discussed below could be termed a second element, component, region, layer or section without departing from the teachings of exemplary embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the apparatus in use or operation in addition to the orientation depicted in the figures. For example, if the apparatus in the figures is turned over, elements described as “below” or “beneath” other elements or features would then be oriented “above” the other elements or features. Thus, the exemplary term “below” can encompass both an orientation of above and below. The apparatus may be otherwise oriented (rotated 90 degrees or at other orientations) and the spatially relative descriptors used herein interpreted accordingly.

The terminology used herein is for the purpose of describing particular exemplary embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. It will be understood that for the purposes of this disclosure, “at least one of X, Y, and Z” can be construed as X only, Y only, Z only, or any combination of two or more items X, Y, and Z (e.g., XYZ, XYY, YZ, ZZ).

Various exemplary embodiments are described herein with reference to crosssectional illustrations that are schematic illustrations of illustratively idealized exemplary embodiments (and intermediate structures) of the inventive concept. As such, variations from the shapes of the illustrations as a result, for example, of manufacturing techniques and/or tolerances, are to be expected. Thus, exemplary embodiments should not be construed as limited to the particular shapes of regions illustrated herein but are to include deviations in shapes that result, for example, from manufacturing. The regions illustrated in the figures are schematic in nature and their shapes are not intended to illustrate the actual shape of a region of an apparatus and are not intended to limit the scope of the inventive concept.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

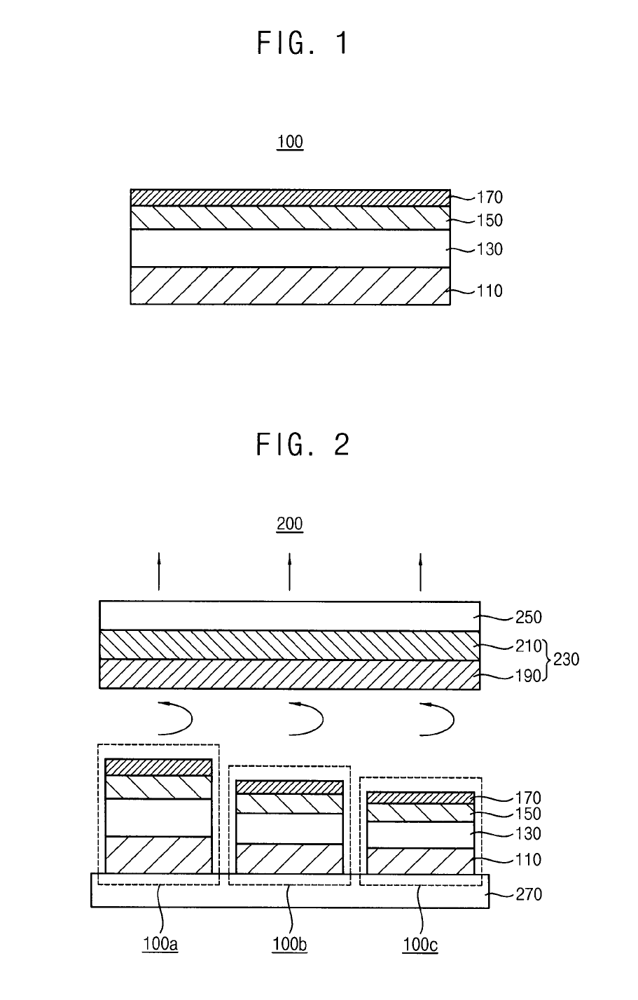

FIG. 1 is a cross-sectional view illustrating a display element in accordance with one exemplary embodiment of the present invention.

Referring to FIG. 1, a display element 100 may include a first electrode 110, an organic emission layer 130, a ferromagnetic electrode 150, and a second electrode 170. The display element 100 may be a non-resonant structure according to one exemplary embodiment.

The first electrode 110 may include a layer of metallic materials. For example, the first electrode 110 may include Ag, Mg, or the like. In one exemplary embodiment, the first electrode 110 may include an anode electrode. Also, in one exemplary embodiment, the first electrode 110 may include a transparent conducting electrode such as transparent conductive oxide (TCO), indium tin oxide (ITO), indium zinc oxide (IZO), and the like.

In accordance with one exemplary embodiment, the organic emission layer 130 may be disposed on the first electrode 110, and the organic emission layer 130 may generate light. The organic emission layer 130 may include a hole injection layer HIL, a hole transporting layer HTL, an emission layer EML, an electron transporting layer ETL, and an electron injection layer EIL, and the organic emission layer 130 may be formed as a stacked structure.

In accordance with one exemplary embodiment, the ferromagnetic electrode 150 may be disposed on the organic emission layer 130. The ferromagnetic electrode 150 may include elements that provide ferromagnetic properties, for instance, at least one of cobalt, iron, lanthanum strontium manganese oxide. The ferromagnetic electrode 150 may control the spin of the light using a magnetic field. The controlled spin may convert the light generated from the organic emission layer 130 in the form of linearly polarized light into right-circularly polarized light or left-circularly polarized light.

The term “spin” may be used to indicate various physical properties in the present disclosure. In accordance with one exemplary embodiment, the spin may mean spin-polarized electrons injected into the emission layer EML from the ferromagnetic electrode 150. In addition, the spin may mean a characteristic of the light changed by the magnetic field. Also, the spin may represent the polarized state of the light, which may include the state of linearly polarized light, circularly polarized light, or the like.

In accordance with one exemplary embodiment, the ferromagnetic electrode 150 and the first electrode 110 may generate a magnetic field. The magnitude of the magnetic field may be controlled to generate circularly polarized light in a wavelength range of visible light having a wavelength of between 380 nm and 780 nm. For instance, the magnitude of the magnetic field may be approximately 3,000 oersted (Oe). In accordance with one exemplary embodiment, spin-polarized electrons may be moved from the ferromagnetic electrode 150 to the electron injection layer EIL, then from the electron injection layer EIL to the electron transporting layer ETL, and then from the electron transporting layer ETL to the emission layer

EML. Subsequently, the spin-polarized electrons may be emitted as light in the emission layer EML, and circularly polarized light may be generated by the magnetic field.

In accordance with one exemplary embodiment, the second electrode 170 may be disposed on the ferromagnetic electrode 150, and the second electrode 170 may oppose the first electrode 110. The second electrode 170 may include a layer of metallic materials. For example, the second electrode 170 may include Ag, Mg, or the like. In one exemplary embodiment, the second electrode 170 may include a cathode electrode. Also, in one exemplary embodiment, the second electrode 170 may include a transparent conducting electrode such as transparent conductive oxide (TCO), indium tin oxide (ITO), indium zinc oxide (IZO), and the like. In one exemplary embodiment, the ferromagnetic electrode 150 may be formed to share the properties of the second electrode 170, and the second electrode 170 may be not disposed on the ferromagnetic electrode 150 in that instance.

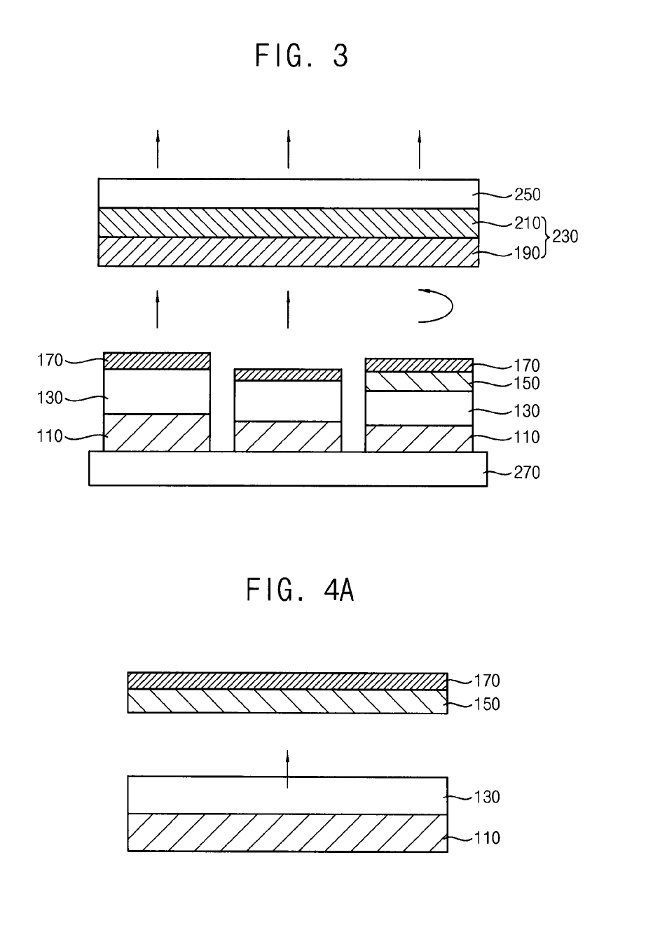

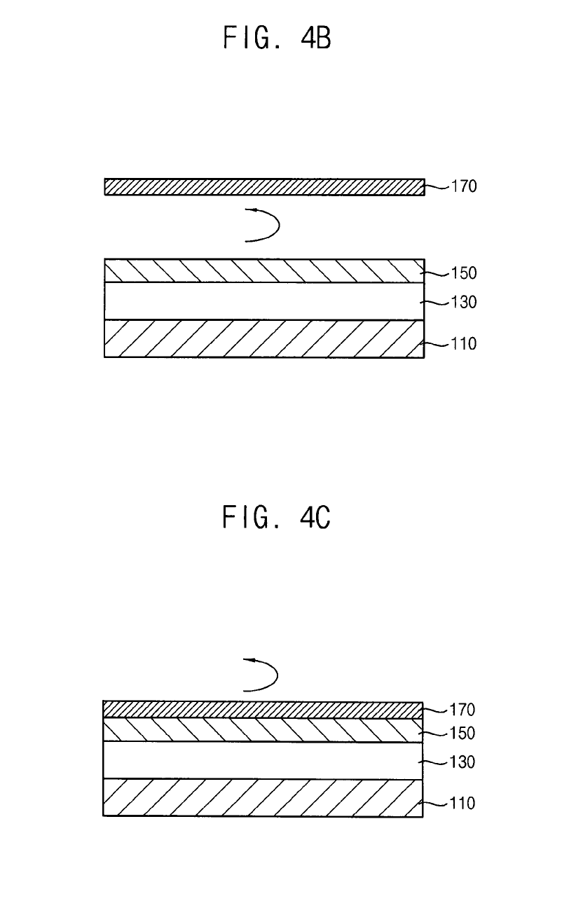

FIG. 2 is a cross-sectional view illustrating a display apparatus in accordance with one exemplary embodiment of the present invention, and FIG. 3 is a cross-sectional view illustrating a display apparatus in accordance with another exemplary embodiment of the present invention.

Referring to FIG. 1 to FIG. 3, a display apparatus 200 includes a first substrate 270, a display element 100a, a display element 100b, a display element 100c, a polarizer 230, and a second substrate 250.

In accordance with one exemplary embodiment, the first substrate 270 may include a transparent insulating substrate. For example, the first substrate 270 may include a glass substrate, a quartz substrate, a polymer resin substrate, or the like. In one exemplary embodiment, the first substrate 270 may include a thin film transistor glass.

In accordance with one exemplary embodiment, the display element 100a, the display element 100b, and the display element 100c may be sequentially (or in any suitable manner) disposed on the first substrate 270. As described in FIG. 1, the display element 100a, the display element 100b, and the display element 100c may be, for instance, a non-resonant structure. Because the display elements 100a, 100b, and 100c may be formed in a similar manner to the display element 100 as shown in FIG. 1, the same explanations will not be repeated. It should be noted that while these exemplary embodiments may be explained with reference to a display device having three display elements, the number of display elements is not limited thereto, and one or more display elements may be used as appropriate and necessary.

The display element 100a, the display element 100b, and the display element 100c may correspond to a red pixel, a green pixel, and a blue pixel, respectively. For example, the display element 100a, which is the thickest stacked structure among the display elements 100a, 100b, and 100c, may form a red pixel, and the display element 100c, which is the thinnest structure, may form a blue pixel, while the display element 100b disposed in the center may form a green pixel. The thickness of those stacking structures may be respectively determined to produce the maximum quantum efficiency value.

In accordance with one exemplary embodiment where a non-resonant structure is employed, the display apparatus may include a display element having at least one of the ferromagnetic electrode 150. For example, the ferromagnetic electrode 150 may be included in at least one of the red display element, the blue display element, and the green display element (as shown in FIGS. 2 and 3).

In accordance with one exemplary embodiment, the polarizer 230 may be disposed on the display elements 100a, 100b, 100c. The polarizer 230 may be substantially in contact with the display element 100a, 100b, 100c according to one exemplary embodiment. The polarizer 230 may include a resin film such as polyvinyl-alcohol PVA. The polarizer 230 may block external light from penetrating in from the external environment. The polarizer 230 may include a linear polarization layer 210 and a λ/4 phase retardation layer 190. As an exemplary structure of the polarizer 230, the linear polarization layer 210 may be disposed on the λ/4 phase retardation layer 190.

The linear polarization layer 210 may selectively transmit light. The linear polarization layer 210 may transmit, for instance, the light vibrating up and down or vibrating left and right. For example, when the pattern of the linear polarization layer 210 includes horizontal stripes, the linear polarization layer 210 blocks light vibrating up and down, and transmits light vibrating left and right. When the pattern of the linear polarization layer 210 includes vertical stripes, the linear polarization layer 210 blocks light vibrating left and right, and transmits light vibrating up and down. In one exemplary embodiment, the linear polarization layer 210 may include vertical stripes.

The λ/4 phase retardation layer 190 may convert the phase of the light. The λ/4 phase retardation layer 190 may convert light vibrating up and down or light vibrating left and right into right-circularly polarized light or left-circularly polarized light, respectively, and may convert right-circularly polarized light or left-circularly polarized light into light vibrating up and down or light vibrating left and right, respectively. For example, λ/4 phase retardation layer 190 may convert right-circularly polarized light into light vibrating up and down, and may convert left-circularly polarized light into light vibrating left and right. Also, the λ/4 phase retardation layer 190 may convert light vibrating up and down into right-circularly polarized light, and may convert light vibrating left and right into left-circularly polarized light.

The second substrate 250 may be disposed on the polarizer 230, and may oppose the first substrate 270. The second substrate 250 may include transparent glass materials. For example, the second substrate 250 may include tempered glass. In one exemplary embodiment, second substrate 250 may include a flexible plastic substrate.

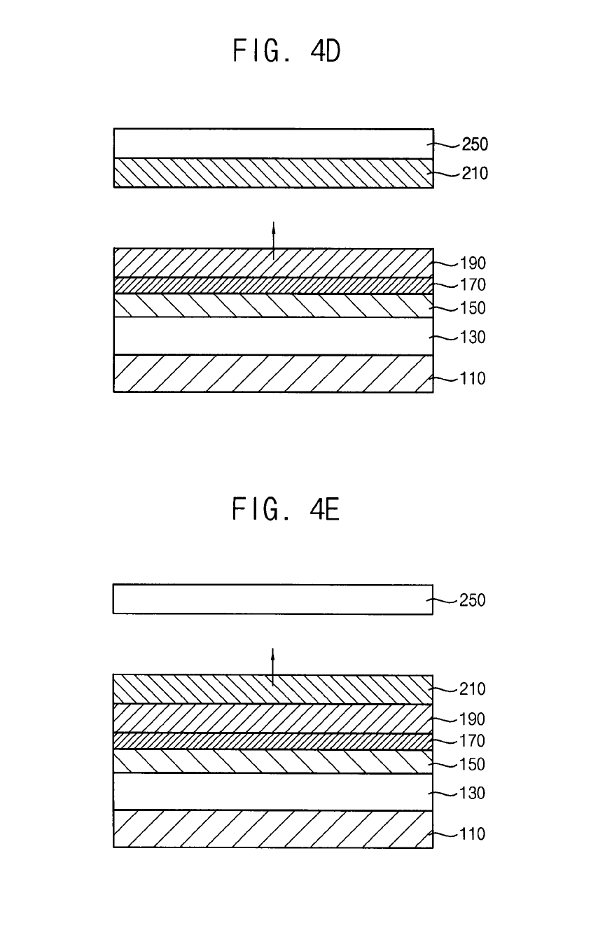

FIGS. 4A to 4F are cross-sectional views illustrating a method of driving the display apparatus of FIG. 2.

Referring to FIG. 4A, the organic emission layer 130 emits light. The light is unpolarized light.

Referring to FIG. 4B, the unpolarized light emitted from the organic emission layer 130 may pass through the ferromagnetic electrode 150. The light may be converted into right-circular polarized light.

Referring to FIG. 4C, the light converted into the right-circularly polarized light may pass through the second electrode 170. In an example that the display element is a non-resonant structure, the thickness of the second electrode 170 may be approximately 60 Å. Thus, the light converted into the right-circular polarized light may pass through the second electrode 170 having a small thickness.

Referring to FIG. 4D, after passing the second electrode 170, the light converted into the right-circularly polarized light may pass through the λ/4 phase retardation layer 190.

When the light converted into the right-circularly polarized light passes the λ/4 phase retardation layer 190, the light may be converted into light vibrating up and down.

Referring to FIG. 4E, the light vibrating up and down may pass through the linear polarization layer 210. The linear polarization layer 210 may include vertical stripes, and thus the light vibrating up and down can pass.

Referring to FIG. 4F, the light vibrating up and down passing the linear polarization layer 210 may pass the second substrate 250.

Accordingly, because the display apparatus 200 having a non-resonant structure includes the ferromagnetic electrode 150, the unpolarized light emitted from the organic emission layer 130 may be converted into circularly polarized light, and thus the brightness of the light emitted from the organic emission layer 130 is not reduced even after passing through the polarizer 230.

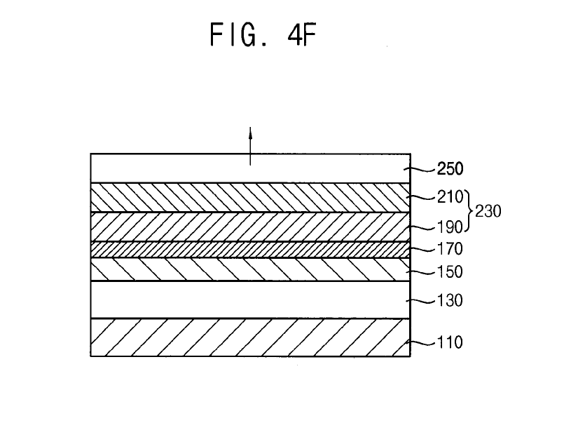

FIG. 5 is a cross-sectional view illustrating a display element in accordance with one exemplary embodiment of the present invention.

Referring to FIG. 5, a display element 300 may include a first electrode 110, a retardation layer 310, an organic emission layer 130, a ferromagnetic electrode 150, and a second electrode 170. The display element 300 may be a resonant structure according to one exemplary embodiment.

The first electrode 110 may include a layer of metallic materials. For example, the first electrode 110 may include Ag, Mg, or the like. In one exemplary embodiment, the first electrode 110 may include an anode electrode. Also, in one exemplary embodiment, the first electrode 110 may include a transparent conducting electrode such as transparent conductive oxide (TCO), indium tin oxide (ITO), indium zinc oxide (IZO), and the like.

In accordance with one exemplary embodiment, the retardation layer 310 may be disposed on the first electrode 110. The retardation layer 310 may change the phase of light. The change of the phase of light may be, for instance, by 180 degrees. In a resonant structure, light may be reflected by the first electrode 110. The light reflected by the first electrode 110 may have a changed phase of light. For example, right-circularly polarized light may be converted into left-circular polarized light, and left-circularly (e.g., counterclockwise) polarized light may be converted into right-circularly (e.g., clockwise) polarized light. In accordance with one exemplary embodiment, the retardation layer 310 may be provided in the display element 300 to return the phase of the light converted by the first electrode 110 to its original phase.

In accordance with one exemplary embodiment, the organic emission layer 130 is disposed on the retardation layer 310, and the organic emission layer 130 may generate light. The organic emission layer 130 may include a hole injection layer HIL, a hole transporting layer HTL, an emission layer EML, an electron transporting layer ETL, and an electron injection layer EIL, and the organic emission layer 130 is formed as a stacked structure.

The ferromagnetic electrode 150 may be disposed on the organic emission layer 130. The ferromagnetic electrode 150 may include at least one of cobalt, iron, lanthanum strontium manganese oxide. The ferromagnetic electrode 150 may control the spin of the light using a magnetic field. The controlled spin may convert the light generated from the organic emission layer 130 from linearly polarized light into right-circularly polarized light or left-circularly polarized light.

In one exemplary embodiment, the spin means spin-polarized electrons injected into the emission layer EML from the ferromagnetic electrode 150. In addition, the spin may mean a characteristic of the light changed by the magnetic field. Also, the spin may represent the polarized state of the light, which may include the state of linearly polarized light, circularly polarized light, or the like.

In accordance with one exemplary embodiment, the ferromagnetic electrode 150 and the first electrode 110 may generate the magnetic field. The magnitude of the magnetic field may be, for instance, about 3,000 oersted (Oe). In fact, the magnitude of the magnetic field may be controlled to generate the circularly polarized light in a wavelength range of visible light having a wavelength of between 380 nm and 780 nm. The spin-polarized electrons may be moved from the ferromagnetic electrode 150 to the electron injection layer EIL, then from the electron injection layer EIL to the electron transporting layer ETL, and then from the electron transporting layer ETL to the emission layer EML. Subsequently, the spin-polarized electrons may be emitted as light in the emission layer EML, and then circularly polarized light may be generated by the magnetic field.

In accordance with one exemplary embodiment, the second electrode 170 may be disposed on the ferromagnetic electrode 150, opposing the first electrode 110. The second electrode 170 may include a layer of metallic materials. For example, the second electrode 170 may include Ag, Mg, or the like. In one exemplary embodiment, the second electrode 170 may include a cathode electrode. Also, in one exemplary embodiment, the second electrode 170 may include a transparent conducting electrode such as transparent conductive oxide (TCO), indium tin oxide (ITO), indium zinc oxide (IZO), and the like. In one exemplary embodiment, the ferromagnetic electrode 150 may be formed to share the properties of the second electrode 170, and the second electrode 170 may be omitted in that instance.

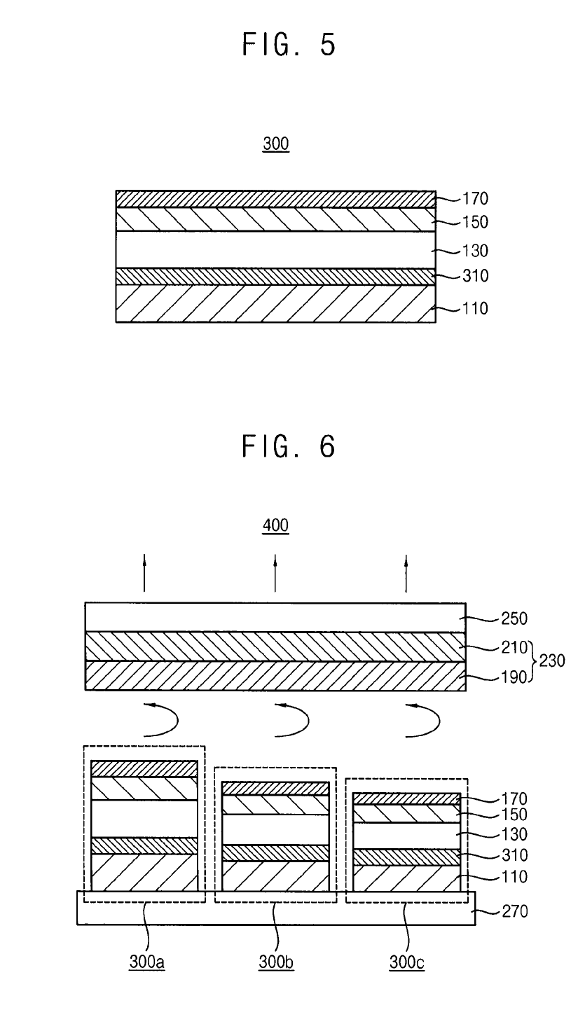

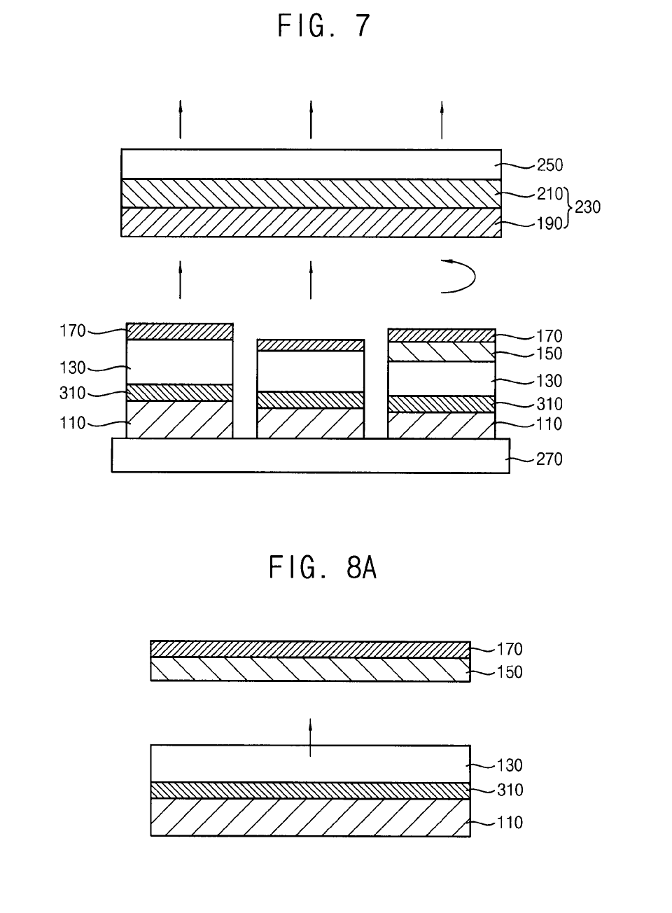

FIG. 6 is a cross-sectional view illustrating a display apparatus in accordance with one exemplary embodiment of the present invention, and FIG. 7 is a cross-sectional view illustrating the display apparatus in accordance with one exemplary embodiment shown in FIG.

6.

Referring to FIG. 5 to FIG. 7, a display apparatus 400 includes a first substrate 270, a display element 300a, a display element 300b, a display element 300c, a polarizer 230, and a second substrate 250.

In accordance with one exemplary embodiment, the first substrate 270 may include a transparent insulating substrate. For example, the first substrate 270 may include a glass substrate, a quartz substrate, a polymer resin substrate, or the like. In one exemplary embodiment, the first substrate 270 may include a thin film transistor glass.

In accordance with one exemplary embodiment, the display element 300a, the display element 300b, and the display element 300c may be sequentially (or in any suitable manner including simultaneously) disposed on the first substrate 270. As described in FIG. 5, the display element 300a, the display element 300b, and the display element 300c may be, for instance, a resonant structure. Because the display elements 300a, 300b, and 300c may be formed in a similar manner to the display element 300 as shown in FIG. 5, the common explanations will not be repeated.

The display element 300a, the display element 300b, and the display element 300c may correspond to a red pixel, a green pixel, and a blue pixel, respectively. For example, the display element 300a, which is the thickest stacked structure among the three display elements, may form a red pixel, and the display element 300c, which is the thinnest stacked structure, may form a blue pixel, while the display element 100b disposed in the center may form a green pixel. The thickness of these stacking structures may be respectively determined to produce the maximum quantum efficiency value.

In one exemplary embodiment where a resonant structure is employed, a display apparatus may include a display element having at least one of the ferromagnetic electrode 150. For example, the ferromagnetic electrode 150 may be included in at least one of the red display element, the blue display element, and the green display element (as shown in FIG. 6).

The polarizer 230 may be disposed on the display elements 300a, 300b, 300c. In accordance with one exemplary embodiment, the polarizer 230 may be substantially in contact with at least one of the display elements 300a, 300b, 300c. The polarizer 230 may include a resin film such as polyvinyl-alcohol PVA. The polarizer 230 may block external light from penetrating in from the external environment. The polarizer 230 may include a linear polarization layer 210 and a λ/4 phase retardation layer 190. As an exemplary structure of the polarizer 230, the linear polarization layer 210 may be disposed on the λ/4 phase retardation layer 190.

The linear polarization layer 210 may selectively transmit light. The linear polarization layer 210 may transmit the light vibrating up and down or vibrating left and right. For example, when the pattern of the linear polarization layer 210 includes horizontal stripes, the linear polarization layer 210 blocks light vibrating up and down, and transmits light vibrating left and right. When the pattern of the linear polarization layer 210 includes vertical stripes, the linear polarization layer 210 blocks light vibrating left and right, and transmits light vibrating up and down. In one exemplary embodiment, the linear polarization layer 210 may include vertical stripes.

The λ/4 phase retardation layer 190 may convert the phase of the light. The λ/4 phase retardation layer 190 may convert light vibrating up and down or light vibrating left and right into right-circularly polarized light or left-circularly polarized light, respectively, and may convert right-circularly polarized light or left-circularly polarized light into light vibrating up and down or light vibrating left and right, respectively. For example, λ/4 phase retardation layer 190 may convert right-circularly polarized light into light vibrating up and down, and may convert left-circularly polarized light into light vibrating left and right. Also, the λ/4 phase retardation layer 190 may convert light vibrating up and down into right-circularly polarized light, and may convert light vibrating left and right into left-circularly polarized light.

The second substrate 250 may be disposed on the polarizer 230, opposing the first substrate 270. The second substrate 250 may include transparent glass materials. For example, the second substrate 250 may include tempered glass. In one exemplary embodiment, second substrate 250 may include a flexible plastic substrate.

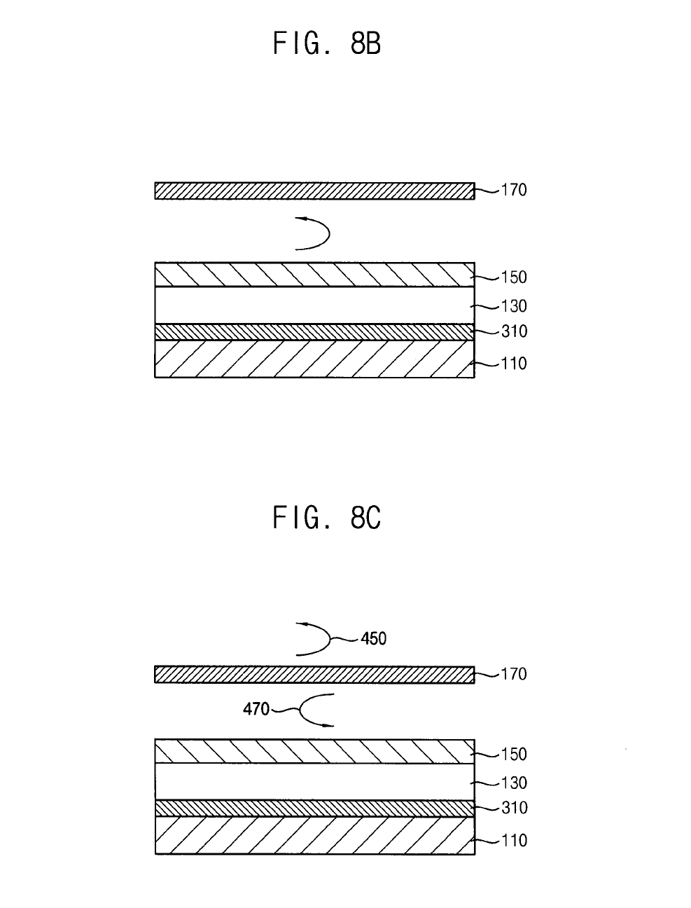

FIGS. 8A to 8J are cross-sectional views illustrating a method of driving the display apparatus of FIG. 6.

Referring to FIG. 8A, the organic emission layer 130 emits light. The light is unpolarized light.

Referring to FIG. 8B, the unpolarized light emitted from the organic emission layer 130 may pass through the ferromagnetic electrode 150. The light may be converted into right-circular polarized light.

Referring to FIG. 8C, the light converted into the right-circularly polarized light may separate the first light 450 that passed through the second electrode 170 and the second light 470 reflected by the second electrode 170. The second light 470 reflected by the second electrode 170 may be converted into left-circularly polarized light.

Referring to FIG. 8D, after the second light 470 being reflected by the second electrode 170, the second light 470 converted into left-circularly polarized light may pass through a retardation layer 310, when the second light 470 passing through the retardation layer 310 may be converted into right-circular polarized light.

Referring to FIG. 8E, the second light 470 converted into the right-circularly polarized light may be reflected by the first electrode 110, and the second light 470 reflected by the first electrode 110 may be converted into left-circular polarized light.

Referring to FIG. 8F, the second light 470 converted into the left-circularly polarized light may pass through the retardation layer 310, and by passing through the retardation layer 310, the second light 470 may be converted into right-circular polarized light.

Referring to FIG. 8G, the second light 470 converted into the right-circular polarized light may pass through the second electrode 170. When the second light 470 passes through the second electrode 170, the first light 450 converted into the right-circular polarized light and the second light 470 may be superposed into the third light 490. In the case of a resonant structure, the thickness of the second electrode 170 may be about 100 Å. Thus, some of the light may pass through the second electrode 170, and some of the light may be reflected by the second electrode 170.

Referring to FIG. 8H, after the third light 490 passes through the second electrode 170, the third light 490 converted into the right-circularly polarized light may pass through the λ/4 phase retardation layer 190. When the third light 490 converted into the right-circularly polarized light passes the λ/4 phase retardation layer 190, the third light 490 converted into the right-circularly polarized light may be converted into light vibrating up and down.

Referring to FIG. 81, the third light 490 vibrating up and down may pass through a linear polarization layer 210. The linear polarization layer 210 may include vertical stripes, and thus the third light 490 vibrating up and down may pass.

Referring to FIG. 8J, the third light 490 vibrating up and down passing the linear polarization layer 210 may pass the second substrate 250.

Accordingly, in the case of the non-resonant structure, because the display apparatus 400 has the ferromagnetic electrode 150, the unpolarized light emitted from the organic emission layer 130 may be converted into circularly polarized light, and thus the brightness of the light emitted from the organic emission layer 130 is not reduced even after passing through the polarizer 230.

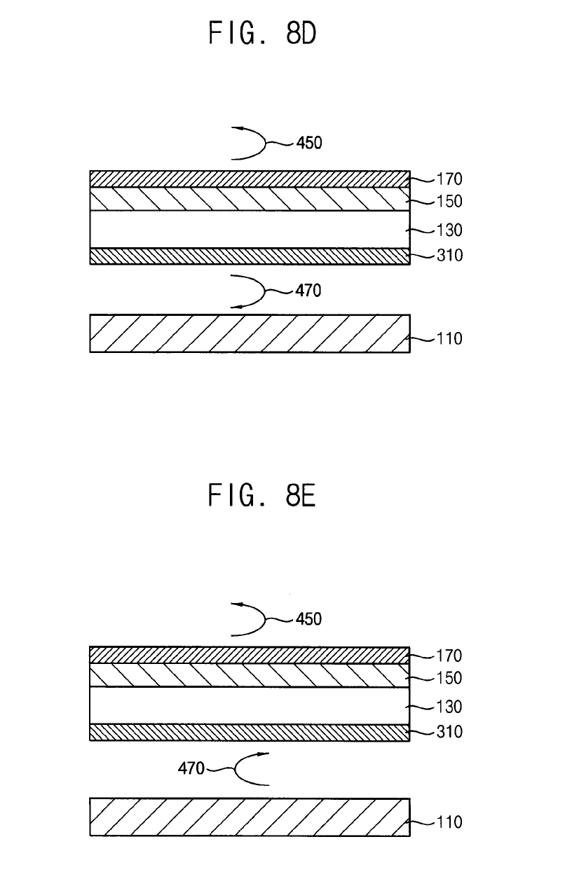

FIG. 9 is a cross-sectional view illustrating a display element in accordance with one exemplary embodiment of the present invention.

Referring to FIG. 9, a display element 500 may include a first electrode 110, an organic emission layer 130, and a ferromagnetic electrode 410. The display element 500 may be a non-resonant structure according to one exemplary embodiment.

The first electrode 110 may include a layer of metallic materials. For example, the first electrode 110 may include Ag, Mg, or the like. In one exemplary embodiment, the first electrode 110 may include an anode electrode. Also, in one exemplary embodiment, the first electrode 110 may include a transparent conducting electrode such as transparent conductive oxide (TCO), indium tin oxide (ITO), indium zinc oxide (IZO), and the like.

The organic emission layer 130 may be disposed on the first electrode 110, and the organic emission layer 130 may generate light. The organic emission layer 130 may include a hole injection layer HIL, a hole transporting layer HTL, an emission layer EML, an electron transporting layer ETL, and an electron injection layer EIL, and the organic emission layer 130 may be formed as a stacked structure.

The ferromagnetic electrode 410 may be disposed on the organic emission layer 130. The ferromagnetic electrode 410 may include elements that provide ferromagnetic properties, for instance, at least one of cobalt, iron, lanthanum strontium manganese oxide. The ferromagnetic electrode 410 may control the spin of the light using a magnetic field. The controlled spin may convert the light generated from the organic emission layer 130 in the form of linearly polarized light into right-circularly polarized light or left-circularly polarized light. In one exemplary embodiment, the ferromagnetic electrode 410 may be used to function as a cathode as well.

In one exemplary embodiment, the term “spin” means spin-polarized electrons injected into the emission layer EML from the ferromagnetic electrode 410. In addition, the spin may mean a characteristic of the light changed by the magnetic field. Also, the spin may represent the polarized state of the light, which includes, for instance, the state of linearly polarized light, circular polarized light, or the like.

In accordance with one exemplary embodiment, the ferromagnetic electrode 410 and the first electrode 110 may generate a magnetic field. The magnitude of the magnetic field may be, for instance, about 3,000 oersted (Oe). In fact, the magnitude of the magnetic field may be controlled to generate circularly polarized light in a wavelength range of visible light having a wavelength of between 380 nm and 780 nm. In accordance with one exemplary embodiment, the spin-polarized electron may be moved from the ferromagnetic electrode 410 to the electron injection layer EIL, then from the electron injection layer EIL to the electron transporting layer ETL, and then from the electron transporting layer ETL to the emission layer EML. Subsequently, the spin-polarized electrons may be emitted as light in the emission layer EML, and circular-polarized light may be generated by the magnetic field.

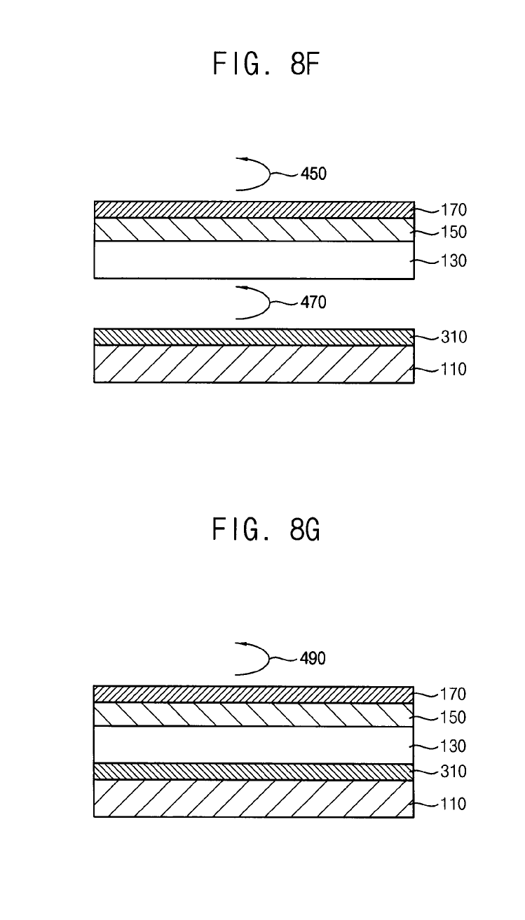

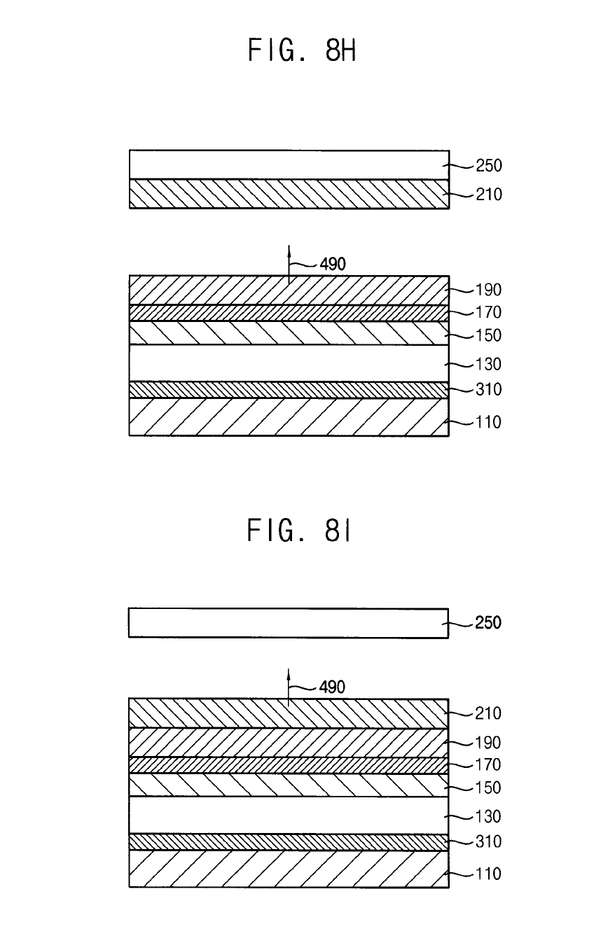

FIG. 10 is a cross-sectional view illustrating a display apparatus in accordance with one exemplary embodiment of the present invention, and FIG. 11 is a cross-sectional view illustrating the display apparatus in accordance with one exemplary embodiment of FIG. 10.

Referring to FIG. 9 to FIG. 11, a display apparatus 600 includes a first substrate 270, a display element 500a, a display element 500b, a display element 500c, a polarizer 230, and a second substrate 250.

The first substrate 270 may include a transparent insulating substrate. For example, the first substrate 270 may include a glass substrate, a quartz substrate, a polymer resin substrate, or the like. In one exemplary embodiment, the first substrate 270 may include a thin film transistor glass.

The display element 500a, the display element 500b, and the display element 500c may be sequentially (or in any suitable order) disposed on the first substrate 270. As described in FIG. 9, the display element 500a, the display element 500b, and the display element 500c are a non-resonant structure. Because the structure of the display element 600 may be formed in a similar manner to the display element 500 shown in FIG. 9, the common explanations will not be repeated.

The display element 500a, the display element 500b, and the display element 500c may form a red pixel, a green pixel, and a blue pixel, respectively. For example, the display element 500a, which is the thickest stacked structure, may correspond to the red pixel, and the display element 500c, which is the thinnest stacked structure, may correspond to the blue pixel, while the display element 500b disposed in the center may correspond to the green pixel. The thickness of the stacking structure may be determined respectively to produce the maximum efficiency value.

In one exemplary embodiment where a non-resonant structure is employed, the display apparatus may include a display element having at least one of the ferromagnetic electrode 410. For example, the ferromagnetic electrode 150 may be included in at least one of a red display element, a blue display element, and a green display element (as shown in FIG. 11).

The polarizer 230 may be disposed on the display elements 500a, 500b, 500c. The polarizer 230 may be substantially in contact with the display element 500a, 500b, 500c according to one exemplary embodiment. The polarizer 230 may include a resin film such as polyvinyl-alcohol PVA. The polarizer 230 may block external light from penetrating in from the external environment. The polarizer 230 may include a linear polarization layer 210 and a λ/4 phase retardation layer 190. As an exemplary structure of the polarizer 230, the linear polarization layer 210 may be disposed on the λ/4 phase retardation layer 190.

The linear polarization layer 210 may selectively transmit light. The linear polarization layer 210 may transmit, for instance, the light vibrating up and down or vibrating left and right. For example, when the pattern of the linear polarization layer 210 includes the horizontal stripes, the linear polarization layer 210 blocks light vibrating up and down, and transmits the light vibrating left and right. When the pattern of the linear polarization layer 210 includes vertical stripes, the linear polarization layer 210 blocks light vibrating left and right, and transmits the light vibrating up and down. In one exemplary embodiment, the linear polarization layer 210 may include vertical stripes.

The λ/4 phase retardation layer 190 may convert the phase of the light. The λ/4 phase retardation layer 190 may convert light vibrating up and down or light vibrating left and right into right-circularly polarized light or left-circularly polarized light, respectively, and may convert right-circularly polarized light or left-circularly polarized light into light vibrating up and down or light vibrating left and right, respectively. For example, λ/4 phase retardation layer 190 may convert right-circularly polarized light into light vibrating up and down, and may convert left-circularly polarized light into light vibrating left and right. Also, the λ/4 phase retardation layer 190 may convert light vibrating up and down into right-circularly polarized light, and may convert light vibrating left and right into left-circularly polarized light.

The second substrate 250 may be disposed on the polarizer 230, opposing the first substrate 270. The second substrate 250 may include transparent glass materials. For example, the second substrate 250 may include tempered glass. In one exemplary embodiment, second substrate 250 may include a flexible plastic substrate.

Accordingly, because the display apparatus 600 having a non-resonant structure has the ferromagnetic electrode 410, the unpolarized light emitted in the organic emission layer 130 may be converted into circularly polarized light, and thus the brightness of the light emitted from the organic emission layer 130 is not reduced as much even after passing through the polarizer 230.

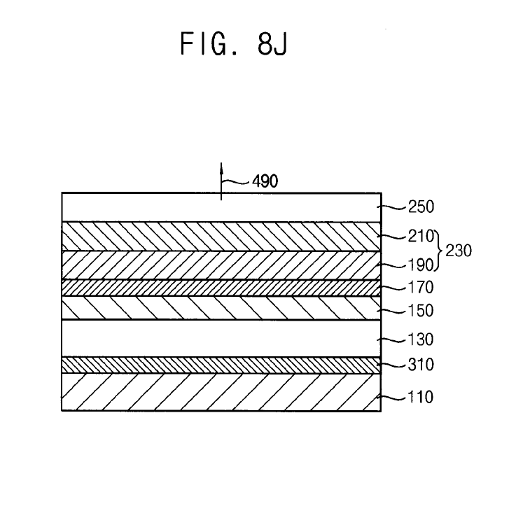

FIG. 12 is a cross-sectional view illustrating a display element in accordance with one exemplary embodiment of the present invention.

Referring to FIG. 12, a display element 700 may include a first electrode 110, an retardation layer 310, an organic emission layer 130, and a ferromagnetic electrode 510. The display element 700 may be a resonant structure.

The first electrode 110 may include a layer of metallic materials. For example, the first electrode 110 may include Ag, Mg, or the like. In one exemplary embodiment, the first electrode 110 may include an anode electrode. Also, in one exemplary embodiment, the first electrode 110 may include a transparent conducting electrode such as transparent conductive oxide (TCO), indium tin oxide (ITO), indium zinc oxide (IZO), and the like.

In accordance with one exemplary embodiment, the retardation layer 310 may be disposed on the first electrode 110. The retardation layer 310 may change the phase of light. The change of the phase of light may be, for instance, 180 degrees. In the case of a resonant structure, the light may be reflected by the first electrode 110. The light reflected by the first electrode 110 may have a changed phase of light. For example, right-circularly polarized light may be converted into left-circularly polarized light, and the left-circularly polarized light may be converted into right-circularly polarized light. The retardation layer 310 may be provided in the display element 700 to return the phase of the light converted by the first electrode 110 to its original phase.

In accordance with one exemplary embodiment, the organic emission layer 130 is disposed on the retardation layer 310, and the organic emission layer 130 may generate light. The organic emission layer 130 may include a hole injection layer HIL, a hole transporting layer HTL, an emission layer EML, an electron transporting layer ETL, and an electron injection layer EIL, and the organic emission layer 130 is formed as a stacked structure.

The ferromagnetic electrode 510 may be disposed on the organic emission layer 130. The ferromagnetic electrode 510 may include at least one of cobalt, iron, lanthanum strontium manganese oxide. The ferromagnetic electrode 510 may control the spin of the light using a magnetic field. The controlled spin may convert the light generated from the organic emission layer 130 from linearly polarized light into right-circularly polarized light or left-circularly polarized light. In one exemplary embodiment, the ferromagnetic electrode 510 may be formed to function as a cathode as well.

In one exemplary embodiment, the spin means spin-polarized electrons injected into the emission layer EML from the ferromagnetic electrode 510. In addition, the spin may mean a characteristic of the light changed by the magnetic field. Also, the spin may represent the polarized state of the light, which may include the state of linearly polarized light, circularly polarized light, or the like.

In accordance with one exemplary embodiment, the ferromagnetic electrode 510 and the first electrode 110 may generate the magnetic field. The magnitude of the magnetic field may be about 3,000 oersted (Oe). In fact, the magnitude of the magnetic field may be controlled to generate the circularly polarized light in a wavelength range of visible light having a wavelength of between 380 nm and 780 nm. The spin-polarized electrons may be moved from the ferromagnetic electrode 510 to the electron injection layer EIL, then from the electron injection layer EIL to the electron transporting layer ETL, and then from the electron transporting layer ETL to the emission layer EML. Subsequently, the spin-polarized electrons may be emitted as light in the emission layer EML, and then circularly polarized light may be generated by the magnetic field.

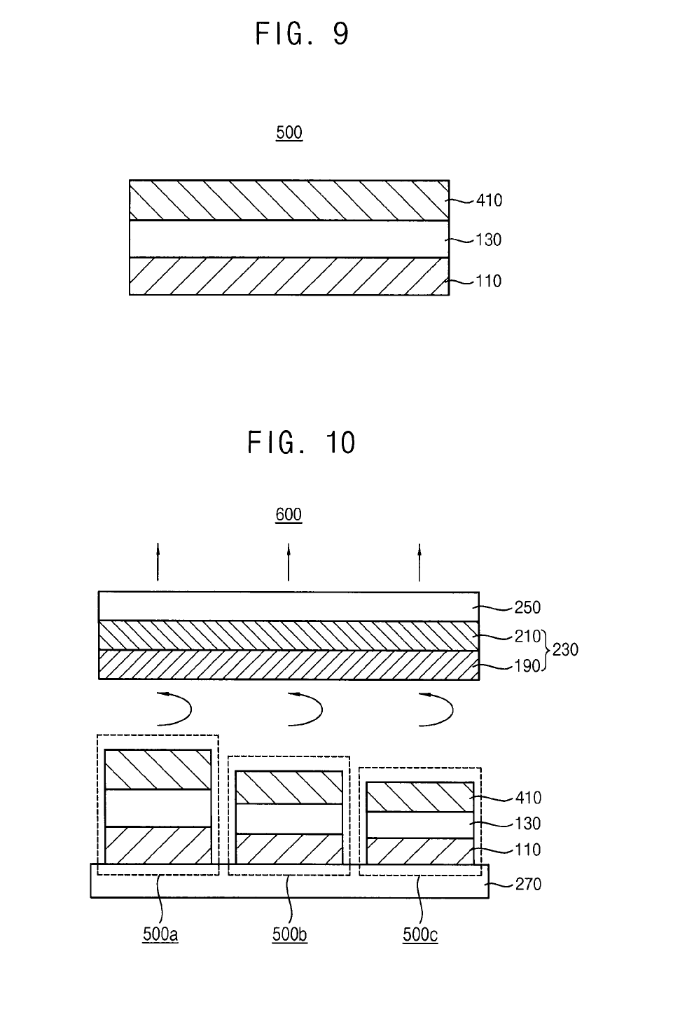

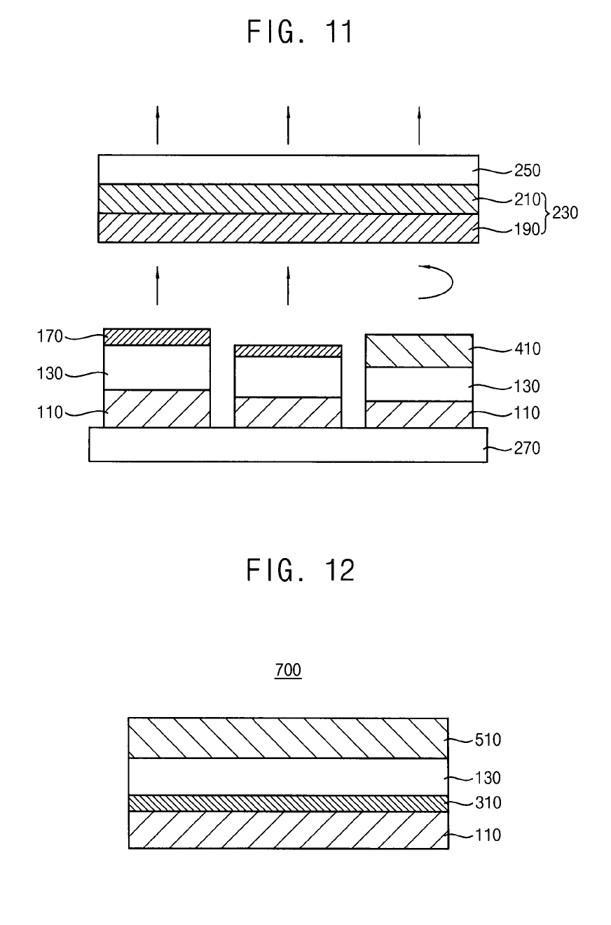

FIG. 13 is a cross-sectional view illustrating a display apparatus in accordance with one exemplary embodiment of the present invention, and FIG. 14 is a cross-sectional view illustrating the display apparatus in accordance with one exemplary embodiment shown in FIG. 13.

Referring to FIG. 12 to FIG. 14, a display apparatus 800 includes a first substrate 270, a display element 700a, a display element 700b, a display element 700c, a polarizer 230, and a second substrate 250.

The first substrate 270 may include a transparent insulating substrate. For example, the first substrate 270 may include a glass substrate, a quartz substrate, a polymer resin substrate, or the like. In one exemplary embodiment, the first substrate 270 may include a thin film transistor glass.

The display element 700a, the display element 700b, and the display element 700c may be sequentially (in any suitable manner such as simultaneously) disposed on the first substrate 270. As described in FIG. 12, the display element 700a, the display element 700b, and the display element 700c are a resonant structure. The structure of the display element 700 shown in FIG. 12 will not be explained about separately because it is formed in a similar manner to the display element shown in FIG. 11.

The display element 700a, the display element 700b, and the display element 700c may form a red pixel, a green pixel, and a blue pixel, respectively. For example, the display element 700a, which is the thickest stacked structure, may form the red pixel, and the display element 700c, which is the thinnest stacked structure, may form the blue pixel, while the display element 700b disposed in the center may form the green pixel. The thickness of these stacked structures may be determined respectively to produce the maximum quantum efficiency value.

In one exemplary embodiment where a resonant structure is employed, the display apparatus may include a display element having at least one of the ferromagnetic electrode 510. For example, the ferromagnetic electrode 150 may be included in at least one of the red display element, the blue display element, and the green display element (as shown in FIG. 14).

The polarizer 230 may be disposed on the display elements 700a, 700b, 700c. In accordance with one exemplary embodiment, the polarizer 230 may be substantially in contact with at least one of the display elements 700a, 700b, 700c. The polarizer 230 may include a resin film such as polyvinyl-alcohol PVA. The polarizer 230 may block external light from penetrating in from the external environment. The polarizer 230 may include a linear polarization layer 210 and a λ/4 phase retardation layer 190. As an exemplary structure of the polarizer 230, the linear polarization layer 210 may be disposed on the λ/4 phase retardation layer 190.

The linear polarization layer 210 may selectively transmit light. The linear polarization layer 210 may transmit the light vibrating up and down or vibrating left and right. For example, when the pattern of the linear polarization layer 210 includes horizontal stripes, the linear polarization layer 210 blocks light vibrating up and down, and transmits the light vibrating left and right. When the pattern of the linear polarization layer 210 includes vertical stripes, the linear polarization layer 210 blocks light vibrating left and right, and transmits light vibrating up and down. In one exemplary embodiment, the linear polarization layer 210 may include vertical stripes.

The λ/4 phase retardation layer 190 may convert the phase of the light. The λ/4 phase retardation layer 190 may convert light vibrating up and down or light vibrating left and right into right-circularly polarized light or left-circularly polarized light, respectively, and may convert right-circularly polarized light or left-circularly polarized light into light vibrating up and down or light vibrating left and right, respectively. For example, λ/4 phase retardation layer 190 may convert right-circularly polarized light into light vibrating up and down, and may convert left-circularly polarized light into light vibrating left and right. Also, the λ/4 phase retardation layer 190 may convert light vibrating up and down into right-circularly polarized light, and may convert light vibrating left and right into left-circularly polarized light.

The second substrate 250 may be disposed on the polarizer 230, opposing the first substrate 270. The second substrate 250 may include transparent glass materials. For example, the second substrate 250 may include tempered glass. In one exemplary embodiment, second substrate 250 may include a flexible plastic substrate.

Accordingly, in the case of a non-resonant structure where the display apparatus 400 has the ferromagnetic electrode 150, the unpolarized light emitted in the organic emission layer 130 may be converted into circularly polarized light, and thus the brightness of the light emitted in the organic emission layer 130 is not reduced as much even after passing through the polarizer 230.

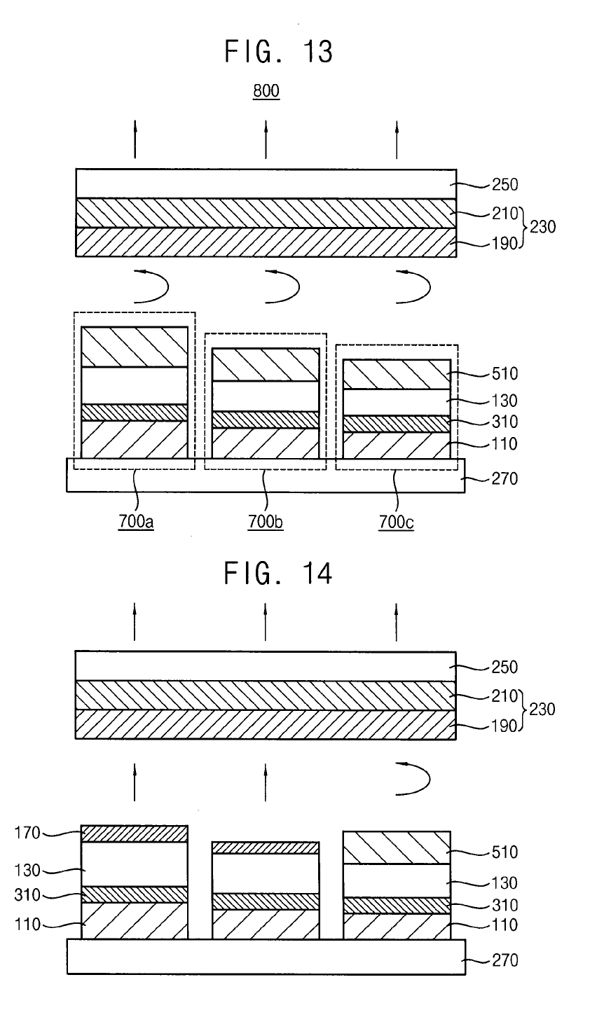

FIG. 15 is a cross-sectional view illustrating a display element in accordance with one exemplary embodiment of the present invention.

Referring to FIG. 15, a display element 900 may include a first electrode 910, a light-shutter element 930, and a ferromagnetic electrode 950.

The first electrode 910 may include a layer of metallic materials. For example, the first electrode 910 may include Ag, Mg, or the like. In one exemplary embodiment, the first electrode 910 may include an anode electrode. Also, in one exemplary embodiment, the first electrode 910 may include a transparent conducting electrode such as transparent conductive oxide (TCO), indium tin oxide (ITO), indium zinc oxide (IZO), and the like.

The light-shutter element 930 may be disposed on the first electrode 910. As the light-shutter element 930 transmits or blocks a light, the light-shutter element 930 may control the transmittance of the light. The light-shutter element 930 may include a liquid crystal display device, an electrophoretic display device, or the like.

The ferromagnetic electrode 950 is disposed on the light-shutter element 930. The ferromagnetic electrode 950 may include at least one of cobalt, iron, lanthanum strontium manganese oxide. The ferromagnetic electrode 950 may control the spin of the light using a magnetic field. The controlled spin may convert the light generated from the organic emission layer 130 from linearly polarized light into right-circularly polarized light or left-circularly polarized light. In one exemplary embodiment, the ferromagnetic electrode 950 may be formed to function as a cathode as well.

In one exemplary embodiment, the spin means spin-polarized electrons injected into the emission layer EML from the ferromagnetic electrode 950. In addition, the spin may mean a characteristic of the light changed by the magnetic field. Also, the spin may represent the polarized state of the light, which includes the state of linearly polarized light, circularly polarized light, or the like.

In accordance with one exemplary embodiment, the ferromagnetic electrode 950 and the first electrode 910 may generate a magnetic field. The magnitude of the magnetic field may be about 3,000 oersted (Oe). The magnitude of the magnetic field may be controlled to generate the circularly polarized light in a wavelength range of visible light having a wavelength of between 380 nm and 780 nm. The spin-polarized electrons may be moved from the ferromagnetic electrode 950 to the electron injection layer EIL, then from the electron injection layer EIL to the electron transporting layer ETL, and then from the electron transporting layer ETL to the emission layer EML. Subsequently, the spin-polarized electrons may be emitted as light in the emission layer EML, and then circularly polarized light may be generated by the magnetic field.

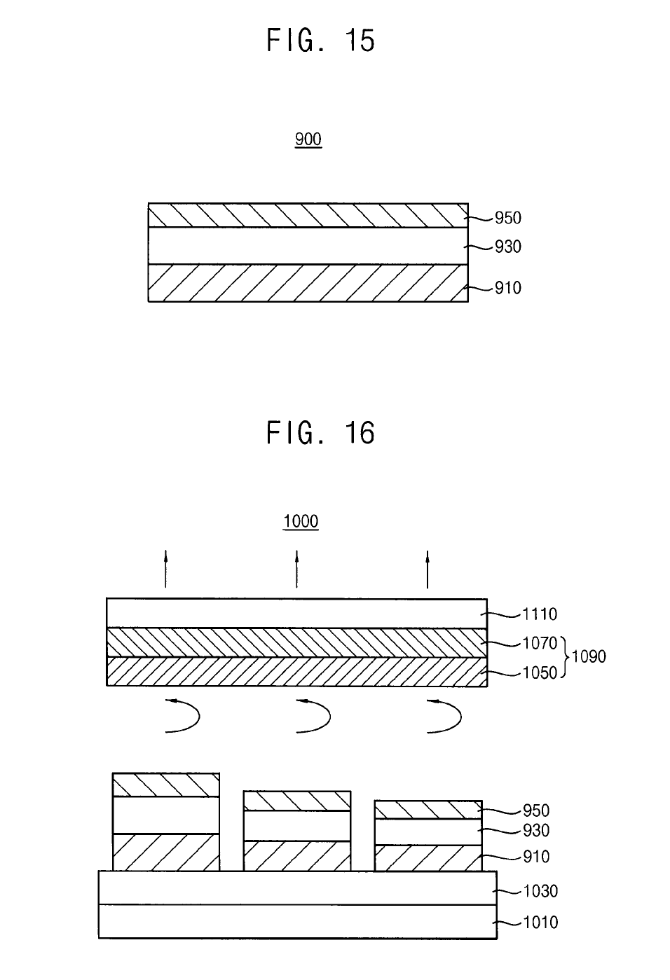

FIG. 16 is a cross-sectional view illustrating a display apparatus in accordance with one exemplary embodiment of the present invention.

Referring to FIG. 16, a display apparatus 1000 includes a first substrate 910, display elements, a polarizer 230, back-light assembly, and a second substrate 1100.

The first substrate 910 may include a transparent insulating substrate. For example, the first substrate 910 may include a glass substrate, a quartz substrate, a polymer resin substrate, or the like. In one exemplary embodiment, the first substrate 910 may include a thin film transistor glass.

The display elements may be sequentially (or in any suitable manner such as simultaneously) disposed on the first substrate 910. Because the structure of the display elements is explained referring to FIG. 15, the same explanations will not be repeated.

The polarizer 1090 may be disposed on the display elements. In accordance with one exemplary embodiment, the polarizer 1090 may be substantially in contact with the display elements. The polarizer 1090 may include a resin film such as polyvinyl-alcohol PVA. The polarizer 1090 may block external light from penetrating in from the external environment. The polarizer 1090 may include a linear polarization layer 1070 and a λ/4 phase retardation layer 1050. As an exemplary structure of the polarizer 1090, the linear polarization layer 1070 may be disposed on the λ/4 phase retardation layer 1050.

The linear polarization layer 1070 may selectively transmit light. The linear polarization layer 1070 may transmit light vibrating up and down or vibrating left and right. For example, when the pattern of the linear polarization layer 1070 includes horizontal stripes, the linear polarization layer 1070 blocks the light vibrating up and down, and transmits the light vibrating left and right. When the pattern of the linear polarization layer 1070 includes vertical stripes, the linear polarization layer 1070 blocks the light vibrating left and right, and transmits the light vibrating up and down. In one exemplary embodiment, the linear polarization layer 1070 may include the vertical stripes.

The λ/4 phase retardation layer 1050 may convert the phase of the light. The λ/4 phase retardation layer 1050 may convert the light vibrating up and down or the light vibrating left and right into the right-circularly polarized light or the left-circularly polarized light, respectively, and may convert the right-circularly polarized light or the left-circularly polarized light into the light vibrating up and down or the light vibrating left and right respectively. For example, λ/4 phase retardation layer 1050 may convert the right-circularly polarized light into the light vibrating up and down, and may convert the left-circularly polarized light into the light vibrating left and right. Also, the λ/4 phase retardation layer 1050 may convert the light vibrating up and down into the right-circularly polarized light, and may convert the light vibrating left and right into the left-circularly polarized light.

The back-light assembly 1010 may include a lamp such as an UV lamp for generating light and a light guide panel which widely distributes the light generated in the lamp. For instance, the wavelength range of a UV lamp may be less than about 400 nm.

The second substrate 1110 may be disposed on the polarizer 1190, and the second substrate 1110 may correspond to the first substrate 1030. The second substrate 1110 may include transparent glass materials. For example, the second substrate 1110 may include tempered glass. In one exemplary embodiment, second substrate 1110 may include a flexible plastic substrate.

Accordingly, because the display apparatus 1000 has the ferromagnetic electrode 950, the unpolarized light emitted in the back-light assembly 1010 may be converted into circularly polarized light, and thus the brightness of the light emitted in the back-light assembly 1010 is not reduced as much even after passing through the polarizer 1090.

Various exemplary embodiments of the present invention may be applied to the entire system having a display apparatus. For example, various exemplary embodiments may be applied to a notebook, a cellular phone, a smartphone, a PDA, a table PC, a navigation system, a GPS, or the like. Also, in the above embodiments, an organic light emitting display device was described as an example, but the spirit of the present invention can also be applied to other display devices such as a liquid crystal display device, electrophoretic display device, plasma display, and the like.

The foregoing is illustrative of exemplary embodiments, and is not to be construed as limiting thereof. Although a few exemplary embodiments have been described, those skilled in the art will readily appreciate that many modifications are possible in the exemplary embodiments without materially departing from the novel teachings and advantages of exemplary embodiments. Accordingly, all such modifications are intended to be included within the scope of exemplary embodiments as defined in the claims. In the claims, means-plus-function clauses are intended to cover the structures described herein as performing the recited function and not only structural equivalents but also equivalent structures. Therefore, it is to be understood that the foregoing is illustrative of exemplary embodiments and is not to be construed as limited to the specific embodiments disclosed, and that modifications to the disclosed exemplary embodiments, as well as other exemplary embodiments, are intended to be included within the scope of the appended claims. The inventive concept is defined by the following claims, with equivalents of the claims to be included therein.

What is claimed is:

1. A display apparatus, comprising:
a first substrate;
a first electrode disposed on the first substrate;
an organic emission layer disposed on the first electrode and configured to generate light;
a ferromagnetic electrode disposed on the organic emission layer and configured to control a spin of the light;
a second electrode disposed on the ferromagnetic electrode, the second electrode opposing the first electrode;
a polarizer disposed on the second electrode and configured to selectively transmit and convert at least part of the light, the polarizer comprising at least two laminated layers; and
a second substrate disposed on the polarizer, the second substrate opposing the first substrate.

2. The display apparatus of claim 1, wherein the ferromagnetic electrode is configured to control the spin of the light by a magnetic field and to convert the light from linearly polarized light into right-circularly polarized light or left-circularly polarized light.

3. The display apparatus of claim 1, wherein the polarizer comprises a linear polarization layer and a λ/4 phase retardation layer, the linear polarization layer of the polarizer being disposed on the λ/4 phase retardation layer.

4. The display apparatus of claim 1, wherein the display apparatus comprises a non-resonant structure.

5. The display apparatus of claim 1, wherein the display apparatus further comprises a retardation layer disposed on the first electrode.

6. The display apparatus of claim 5, wherein the display apparatus comprises a resonant structure.

7. A method of driving a display apparatus, the method comprising:
generating light;
passing the light through a ferromagnetic electrode to convert a polarization state of the light;
passing the light through a second electrode;
passing the light through a λ/4 phase retardation layer, thereby converting the light into right-circularly polarized light;
converting the light to vibrate up and down;
passing the light through a linear polarization layer; and
passing the light vibrating up and down through a second substrate to enable a display of an image.

8. The method of claim 7, wherein passing the light through a ferromagnetic electrode comprises the ferromagnetic electrode controlling a spin of the light emitted from an organic emission layer using a magnetic field to convert the polarization state into right-circularly polarized light.

9. The method of claim 8, wherein the display apparatus comprises a non-resonant structure.

10. A method of driving a display apparatus, the method comprising:
generating light;
passing the light through a ferromagnetic electrode to convert the light into right-circularly polarized light;
causing the light to separate into first light and second light, the first light passing through a second electrode, and the second light being reflected from the second electrode;
converting the second light into left-circularly polarized light;
passing the second light through a retardation layer;
converting the passed second light into right-circularly polarized light;
reflecting the second light from a first electrode;
converting the reflected second light into left-circularly polarized light;
passing the second light through the retardation layer;
converting the second light into right-circularly polarized light;
passing the second light through the second electrode;
superposing the first light and the second light in the form of the right-circular polarized light to generate third light;
passing the third light through a λ/4 phase retardation layer, the superposed third light being the right-circular polarized light;
converting the third light to vibrate up and down;
passing the third light through a linear polarization layer; and
passing the light through a second substrate to enable a display of an image.

11. The method of claim 10, wherein passing the light through a ferromagnetic electrode comprising the ferromagnetic electrode controlling a spin of the light emitted from an organic emission layer using a magnetic field to convert the polarization state of the light into the right-circularly polarized light.

12. The method of claim 10, wherein the display apparatus comprises a non-resonant structure.

13. A display apparatus, comprising:
a first substrate;
a first electrode disposed on the first substrate;
an organic emission layer disposed on the first electrode and configured to generate light;
a ferromagnetic electrode disposed on the organic emission layer and configured to control a spin of the light, the ferromagnetic electrode opposing the first electrode;
a polarizer disposed on the ferromagnetic electrode and configured to selectively transmit and convert at least part of the light, the polarizer comprising at least two laminated layers; and
a second substrate disposed on the polarizer, the second substrate opposing the first substrate.

14. The display apparatus of claim 13, wherein the ferromagnetic electrode comprises a cathode electrode.

15. The display apparatus of claim 13, wherein the ferromagnetic electrode is configured to control the spin of the light by a magnetic field and to convert the light from linearly polarized light into right-circularly polarized light or left-circularly polarized light.

16. The display apparatus of claim 13, wherein the polarizer comprises a linear polarization layer and a λ/4 phase retardation layer, the linear polarization layer of the polarizer being disposed on the λ/4 phase retardation layer.
